(19) United States
(12) Patent Application Publication
(10) Pub. No.: US 2012/0314189 A1
(43) Pub. Date: Dec. 13, 2012

(54) LIGHT EMITTING ELEMENT, LIGHT SOURCE DEVICE, AND PROJECTION DISPLAY DEVICE

(75) Inventors: Masanao Natsumeda, Tokyo (JP); Masao Imai, Tokyo (JP); Naofumi Suzuki, Tokyo (JP); Shin Tominaga, Tokyo (JP)

(73) Assignee: NEC CORPORATION, Minato-ku, Tokyo (JP)

(21) Appl. No.: 13/580,707

(22) PCT Filed: Oct. 14, 2010
(86) PCT No.: PCT/JP2010/068013

§ 371 Date: Aug. 23, 2012

(30) Foreign Application Priority Data
Mar. 10, 2010 (JP) 2010-053094

(51) Int. Cl. H01L 33/58; G03B 21/14

(52) U.S. Cl. 353/20; 257/98; 257/E33.068

(57) ABSTRACT

The present invention includes light source layer (4) and directivity controlling layer (5) into which light emitted from light source layer (4) enters. Light source layer (4) has a pair of hole transport layer (11) and electron transport layer (13) formed on substrate (10). Directivity controlling layer (5) has plasmon excitation layer (15) that is laminated on non-substrate (10) side of light source layer (4) and that has a higher plasma frequency than light emitted from light source layer (4) and wave number vector conversion layer (17) that converts surface plasmons that are generated in plasmon excitation layer (15) into light having a predetermined emission angle and emits the light having the predetermined emission angle. Plasmon excitation layer (15) is sandwiched between two layers having dielectricity. The effective dielectric constant of the incident side portion including the entire structure laminated on light source layer (4) side of plasmon excitation layer (15) is greater than that of the emission side portion including the entire structure laminated on wave number vector conversion layer (17) side of plasmon excitation layer (15) and a medium that contacts wave number vector conversion layer (17).

### TECHNICAL FIELD

The present invention relates to a light emitting element, a light source device, and a projection display device that use surface plasmons to emit light.

### BACKGROUND ART

An LED projector that uses a light emitting diode (LED) as a light emitting element for a light source has been proposed. The LED projector of this type has an illumination optical system into which light emitted from the LED enters; a light valve having a liquid crystal display panel into which light emitted from the illumination optical system enters and a DMD (Digital Micromirror Device); and a projection optical system that projects light emitted from the light valve to a projection plane.

A requirement for the LED projector is that be a minimum of optical loss in the optical path from the LED to the light valve so as to improve the luminance of projected images.

In addition, as described in Non-Patent Literature 1, the LED projector is restricted by the etendue that depends on the product of the area and emission angle of the light source. In other words, light emitted from the light source cannot be used as projection light unless the product of the light emission area and emission angle of the light source is equal to or smaller than the product of the area of the incident plane of the light valve and the acceptance angle (solid angle) that depends on the F number of the optical system.

Thus, there has been a demand to reduce the etendue of light emitted from the LED so as to reduce the foregoing optical loss.

The light source for an LED projector needs to emit a light beam in the order of several thousand lumens. To realize such a light source, an LED that has high luminance and high directivity is essential.

As an example of a light emitting element that has high luminance and high directivity, Patent Literature 1 discloses a semiconductor light emitting element having a structure shown in FIG. 1 in which n-type GaN layer 102, InGaN active layer 103, p-type GaN layer 104, ITO transparent electrode layer 105, and two-dimensional periodic structure layer 109 are successively stacked on sapphire substrate 101. Groove 108 is formed by cutting part of the light emitting element. The light emitting element also has n-side bonding electrode 106 partly formed on n-type GaN layer 102 buried in groove 108 and p-side bonding electrode 107 formed on ITO transparent electrode layer 105. In this light emitting element, two-dimensional periodic structure layer 109 improves the directivity of light emitted from InGaN active layer 103. As a result, the light emitting element emits light having improved directivity.

As another example of a light emitting element having high luminance and high directivity, Patent Literature 2 discloses organic EL element 110 having a structure shown in FIG. 2 in which anode layer 112, hole transport layer 113, light emitting layer 114, electron transport layer 115, and cathode 116 having fine periodic uneven structural grating 116a are successively stacked on substrate 111. This light emitting element uses the fine periodic uneven structural grating 116a of cathode 116 and the effect of surface plasmons that propagate on the interface with the outside to realize high directivity that allows the emission angle of light that is emitted from the light emitting element to be less than ±15°.

### PATENT LITERATURE

Patent Literature 1: JP2005-005679A, Publication
Patent Literature 2: JP2006-313667A, Publication

### NON-PATENT LITERATURE

Non-Patent Literature 1: PhlatLight™ Photonic Lattice LEDs for RPTV Light Engines; Christine Hoepfner; SID Symposium Digest 37, 1808 (2006)

### SUMMARY OF INVENTION

As described above, light emitted from the light emitting element at a constant angle exceeding a predetermined angle (for example, an emission angle of ±15°) does not enter the illumination optical system and the light valve, but becomes optical loss. So far, as the structure described in Patent Literature 1, an LED that emits a light beam in the order of several thousand lumens has been realized. Although this structure can achieve high luminance, it cannot narrow the emission angle of light that is emitted from the light emitting element to less than ±15°. In other words, the light emitting element described in Patent Literature 1 has a drawback in which the directivity of emission light is low.

On the other hand, the structure described in Patent Literature 2 uses surface plasmons so as to narrow the emission angle of emission light to less than ±15°. However, so far, an organic EL element that emits a light beam in the order of several thousand lumens does not existed. Thus, there is a problem in which, even if the light emitting element described in Patent Literature 2 is applied to an LED projector, sufficient luminance can not be obtained.

In other words, the structures disclosed in Patent Literatures 1 and 2 have not realized light emitting elements that satisfy both luminance and directivity that an LED projector requires.

An object of the present invention is to provide a light emitting element that can solve the forgoing engineering problems and also provides a light source device and a projection display device that are equipped with such a light emitting element.

To realize the foregoing object, a light emitting element according to the present invention includes a light source layer and an optical element layer that is stacked on the light source layer and into which light emitted from the light source layer enters. The light source layer has a substrate and a pair of a hole transport layer and an electron transport layer formed on the substrate. The optical element layer has a plasmon excitation layer that is stacked on a non-substrate side of the light source layer and that has a higher plasma frequency than light emitted from the light source layer and an emission layer that is stacked on the plasmon excitation layer and that converts surface plasmons that are generated in the plasmon excitation layer into light having a predetermined exit angle and emits the light having the predetermined exit angle. The plasmon excitation layer is sandwiched between two layers having dielectricity. The effective dielectric constant of an incident side portion including an entire structure stacked on the light source layer side of the plasmon excitation layer is greater than that of an emission side portion including an entire structure stacked on the emission layer side of the plasmon excitation layer and a medium that contacts the emission layer.

A light source device according to the present invention includes a light emitting element of the present invention and a polarization conversion element that aligns axially symmetric polarized light that enters from the light emitting element in a predetermined polarization state.

A projection display device according to the present invention includes a light emitting element of the present invention, a display element that modulates light emitted from the emitting element, a projection optical system that projects an image with light emitted from the emitting element, and a polarization conversion element that is arranged on an optical path between the light emitting element and the display element and that aligns axially symmetric polarized light that enters from the light emitting element into a predetermined polarization state.

According to the present invention, since both luminance and directivity of emission light can be improved, a light emitting element that has high luminance and high directivity can be realized.

### BRIEF DESCRIPTION OF DRAWINGS

FIG. 1 is a perspective view describing the structure of Patent Literature 1.

FIG. 2 is a sectional view describing the structure of Patent Literature 2.

FIG. 3A is a perspective view schematically showing the structure of a light emitting element according to an embodiment of the present invention.

FIG. 3B is a plan view schematically showing the light emitting element according to the embodiment.

FIG. 4A is a perspective view schematically showing the structure of a light emitting element according to a second embodiment.

FIG. 4B is a plan view schematically showing the light emitting element according to the second embodiment.

FIG. 5A is a sectional view describing a manufacturing process of the light emitting element according to the second embodiment.

FIG. 5B is a sectional view describing the manufacturing process of the light emitting element according to the second embodiment.

FIG. 5C is a sectional view describing the manufacturing process of the light emitting element according to the second embodiment.

FIG. 5D is a sectional view describing the manufacturing process of the light emitting element according to the second embodiment.

FIG. 5E is a sectional view describing the manufacturing process of the light emitting element according to the second embodiment.

FIG. 5F is a sectional view describing the manufacturing process of the light emitting element according to the second embodiment.

FIG. 6A is a perspective view schematically showing the structure of a light emitting element according to a third embodiment.

FIG. 6B is a plan view schematically showing the light emitting element according to the third embodiment.

FIG. 7A is a perspective view schematically showing the structure of a light emitting element according to a fourth embodiment.

FIG. 7B is a plan view schematically showing the light emitting element according to the fourth embodiment.

FIG. 8 is a perspective view schematically showing a directivity controlling layer of a light emitting element according to a fifth embodiment.

FIG. 9 is a perspective view schematically showing a directivity controlling layer of a light emitting element according to a sixth embodiment.

FIG. 10 is a perspective view schematically showing a directivity controlling layer of a light emitting element according to a seventh embodiment.

FIG. 11 is a perspective view schematically showing a directivity controlling layer of a light emitting element according to an eighth embodiment.

FIG. 12 is a perspective view schematically showing a directivity controlling layer of a light emitting element according to a ninth embodiment.

FIG. 13A is a perspective view schematically showing the structure of a light emitting element according to a tenth embodiment.

FIG. 13B is a plan view schematically showing the light emitting element according to the tenth embodiment.

FIG. 14 is a perspective view showing an axially symmetric polarization half wave plate applied to a light emitting element according to an embodiment of the present invention.

FIG. 15 is a transverse sectional view showing the structure of the axially symmetric polarization half wave plate applied to the light emitting element according to the embodiment.

FIG. 16A is a schematic diagram describing the axially symmetric polarization half wave plate applied to the light emitting element according to the embodiment.

FIG. 16B is a schematic diagram describing the axially symmetric polarization half wave plate applied to the light emitting element according to the embodiment.

FIG. 17 is a schematic diagram showing a far-field pattern and a polarization direction of emission light in a case in which the light emitting element according to the embodiment is not provided with an axially symmetric polarization half wave plate.

FIG. 18 is a schematic diagram showing a far-field pattern and a polarization direction of emission light in a case in which the light emitting element according to the embodiment is provided with an axially symmetric polarization half wave plate.

FIG. 19 is a schematic diagram showing an angle distribution of light emitted from the emitting element according to the second embodiment.

FIG. 20 is a schematic diagram showing an angle distribution of light emitted from the emitting element according to the fifth embodiment.

FIG. 21 is a schematic diagram comparing a plasmon resonance angle obtained from an effective dielectric constant with that obtained from a multilayer film reflection calculation with respect to the light emitting element according to the fifth embodiment.

FIG. 22 is a perspective view schematically showing an LED projector to which the light emitting element according to an embodiment is applied.

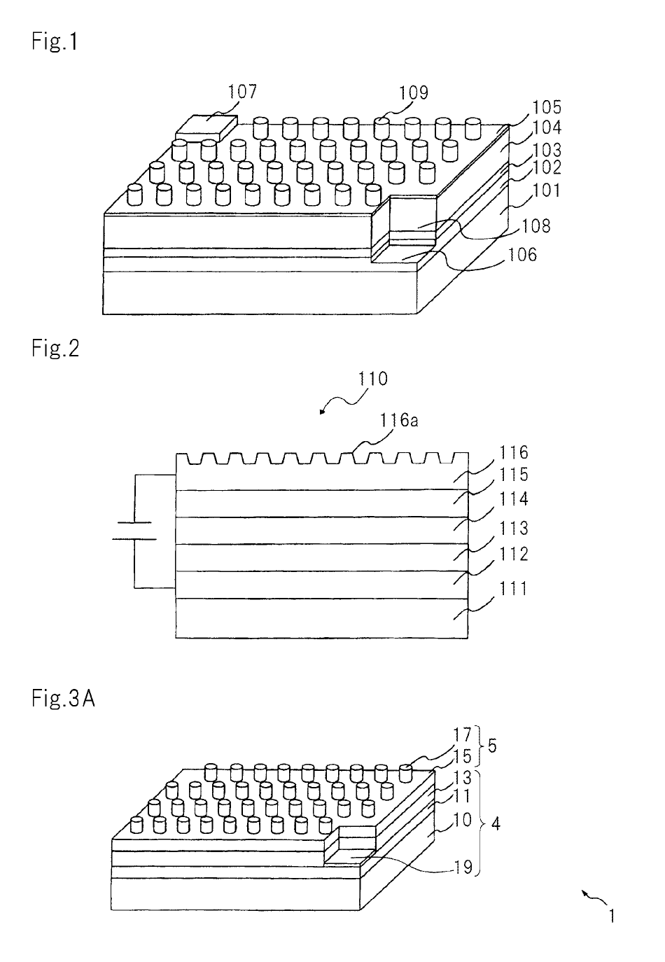

### DESCRIPTION OF EMBODIMENTS

Next, with reference to the accompanying drawings, concrete embodiments of the present invention will be described.

### First Embodiment

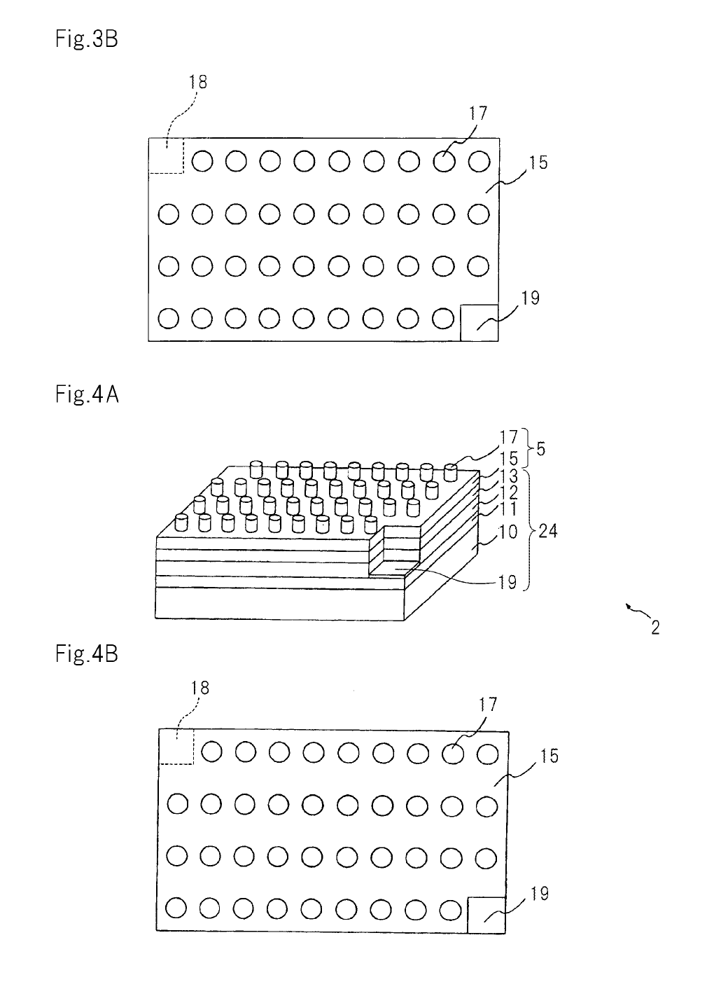

FIG. 3A is a perspective view schematically showing the structure of a light emitting element according to a first embodiment of the present invention. FIG. 3B is a plan view schematically showing the light emitting element according to this embodiment. Since the individual layers of the light emitting element are very thin and their thickness largely differ, it is difficult to illustrate the individual layers in the exact scales. Thus, the drawings do not illustrate the individual layers in the exact scales, but schematically illustrate them.

As shown in FIG. 3A, light emitting element 1 according to the first embodiment has light source layer 4 and directivity controlling layer 5 that is stacked on light source layer 4 and that operates as an optical element layer into which light emitted from light source layer 4 enters.

Light source layer 4 has substrate 10 and a pair of hole transport layer 11 and electron transport layer 13 that are formed on substrate 10. Stacked successively on substrate 10 are hole transport layer 11 and electron transport layer 13.

Directivity controlling layer 5 is formed on an opposite side of substrate 10 of light source layer 4. Directivity controlling layer 5 has plasmon excitation layer 15 that has a higher plasmon frequency than the frequency of light emitted from light source layer 4; and wave number vector conversion layer 17 as an emission layer that is stacked on plasmon excitation layer 15 and that converts incident light of plasmon excitation layer 15 into a predetermined exit angle and emits the resultant light.

As shown in FIG. 3A and FIG. 3B, upper layers of hole transport layer 11 are partly cut such that part of a plane orthogonal to the direction of the thickness of hole transport layer 11 is exposed. Anode 19 is formed at the exposed portion of hole transport layer 11. Likewise, part of wave number vector conversion layer 17 formed on plasmon excitation layer 15 is cut such that part of a plane orthogonal to the direction of the thickness of plasmon excitation layer 15 is exposed. The exposed portion of plasmon excitation layer 15 operates as cathode 18. Thus, in the structure of this embodiment, electrons are injected from plasmon excitation layer 15, whereas holes (positive holes) are injected from anode 19.

Alternatively, the relative positions of electron transport layer 13 and hole transport layer 11 of light source layer 4 may be reverse of those according to this embodiment. A cathode made of a material different from that of plasmon excitation layer 15 may be formed partly or entirely on plasmon excitation layer 15 that is exposed. The cathode and anode may be those that compose an LED or an organic EL. If the cathode is formed completely on the exposed plane of plasmon excitation layer 15, it is preferable that the cathode be transparent at a frequency of emission light of light source layer 4.

The ambient medium of light emitting element 1 may be either solid, liquid, or gaseous. In addition, the ambient medium on substrate 10 side of light emitting element 1 may be different from that on wave number vector conversion layer 17 side of light emitting element 1.

Hole transport layer 11 may be made of, for example, a p-type semiconductor that composes an ordinary LED or a semiconductor laser; or an aromatic amine compound or tetraphenyldiamine that is a hole transport layer used for an organic EL.

Electron transport layer 13 may be made of an n-type semiconductor that composes an ordinary LED or a semiconductor laser; Alq3 that is an electron transport layer for an organic EL; oxadiazolium (PBD); or triazole (TAZ).

FIG. 3A also shows a basic structure of light source layer 4 of light emitting element 1 according to the present invention. Formed between each layer of light source layer 4 may be other layers for example a buffer layer, another hole transport layer, and another electron transport layer. Alternatively, light source layer 4 may have a structure of a known LED or organic EL.

Formed between hole transport layer 11 and substrate 10 of light source layer 4 may be a reflection layer (not shown) that reflects light emitted from active layer 12. In this structure, the reflection layer may be, for example, a metal film made of Ag or Al or a multi-layer dielectric substance layer.

Plasmon excitation layer 15 is sandwiched between two layers having dielectricity. According to this embodiment, these two layers correspond to electron transport layer 13 and wave number vector conversion layer 17. Light emitting element 1 according to this embodiment is structured such that the effective dielectric constant of the incident side portion including the entire structure stacked on light source layer 4 side of plasmon excitation layer 15 (hereinafter referred to as the incident side portion) is greater than that of the emission side portion including the entire structure stacked on wave number vector conversion layer 17 side of plasmon excitation layer 15 and a medium that contacts wave number vector conversion layer 17 (hereinafter referred to as the emission side portion). The entire structure stacked on wave number vector conversion layer 17 side of plasmon excitation layer 15 includes wave number vector conversion layer 17.

In other words, according to the first embodiment, the effective dielectric constant of the incident side portion including entire light source layer 4 with respect to plasmon excitation layer 15 is greater than that of the emission side portion including wave number vector conversion layer 17 and the medium with respect to plasmon excitation layer 15.

Specifically, the real part of the complex effective dielectric constant of the incident side portion (light source layer 4 side) of plasmon excitation layer 15 is set to be greater than the real part of the complex effective dielectric constant of the emission side portion (wave number vector conversion layer 17 side) of plasmon excitation layer 15.

Assuming that directions in parallel with an interface of plasmon excitation layer 15 are denoted by x and y axes; a direction perpendicular to the interface of plasmon excitation layer 15 is denoted by z axis; an angular frequency of emission light of light source layer 4 is denoted by ω; a dielectric constant distribution of a dielectric substance at the incident side portion or emission side portion with respect to plasmon excitation layer 15 is denoted by ∈ (ω, x, y, z), the wave number of surface plasmons is denoted by k_{spp,z}; and an imaginary unit is denoted by j, then a complex effective dielectric constant ∈_{eff} can be expressed as follows.

$$\begin{matrix}[ Formula 1 ] & \\ {ɛ}_{eff} = \frac{{\int \int \int }_{D} ɛ ( ω , x , y , z ) exp ( 2 j {k}_{app , z} z )}{{\int \int \int }_{D} exp ( z )} & Formula ( 1 )\end{matrix}$$

An integration range D is a range of the incident side portion or emission side portion in a three dimensional coordination with respect to plasmon excitation layer 15. In other words, the ranges in the directions of the x axis and y axis in the integration range D are ranges that do not include a medium on the outer circumferential plane of the structure that the incident side portion or emission side portion includes, but ranges that include the outer edge of a plane in parallel with the interface of plasmon excitation layer 15. On the other hand, the range in the direction of the z axis in the integration range D is the range of the incident side portion or emission side portion (including the medium). It is assumed that the interface between plasmon excitation layer 15 and a layer that has dielectricity and that is adjacent to plasmon excitation layer 15 is at the position where z=0, that the range in the direction of the z axis in the integration range D is a range from the interface to infinity on the foregoing adjacent layer side of plasmon excitation layer 15, and that the direction that is apart from the interface is referred to as the (+) z direction in Formula (1).

On the other hand, assuming that the real part of the dielectric constant of plasmon excitation layer 15 is denoted by ∈ₘₑₜₐₗ and the wave number of light in vacuum is denoted by k₀, a z component of the wave number of surface plasmons, k_{spp,z}, and x and y components of the wave number of the surface plasmons, kₛₚₚ, can be expressed as follows.

$$\begin{matrix}[ Formula 2 ] & \\ {k}_{spp , z} = \sqrt{{ɛ}_{eff} {k}_{0}^{2} - {k}_{spp}^{2}} & Formula ( 2 ) \\ [ Formula 3 ] & \\ {k}_{spp} = {k}_{0} \sqrt{\frac{{ɛ}_{eff} {ɛ}_{metal}}{{ɛ}_{eff} + {ɛ}_{metal}}} & Formula ( 3 )\end{matrix}$$

Thus, by inserting a dielectric constant distribution ∈ᵢₙ (ω, x, y, z) of the incident side portion of plasmon excitation layer 15 and a dielectric constant distribution ∈ₒᵤₜ (ω, x, y, z) of the emission side portion of plasmon excitation layer 15 as ∈ (ω, x, y, z) into Formula (1), Formula (2), and Formula (3), a complex effective dielectric constant ∈_{effin} of the incident side portion with respect to plasmon excitation layer 15 and a complex effective dielectric constant ∈_{effout} of the emission side portion with respect to plasmon excitation layer 15 are obtained. In practice, by giving an appropriate initial value as a complex effective dielectric constant ∈_{eff} and iteratively calculating Formula (1), Formula (2) and Formula (3), the complex effective dielectric constant ∈_{eff} can be easily obtained. If the real part of the dielectric constant of the layer that contacts plasmon excitation layer 15 is very large, the z component k_{spp,z} of the wave number of the surface plasmons on the interface becomes a real number. This means that no surface plasmons occur on the interface. Thus, the dielectric constant of the layer that contacts plasmon excitation layer 15 corresponds to the effective dielectric constant in this case.

Assuming that an effective interaction distance of surface plasmons is a distance for which the intensity of surface plasmons becomes e⁻², the effective interaction distance d_{eff} of the surface plasmons can be expressed as follows.

$$\begin{matrix}[ Formula 4 ] & \\ {d}_{eff} = Im [ \frac{1}{{k}_{spp , z}} ] & Formula ( 4 )\end{matrix}$$

It is preferable that the imaginary part of the complex dielectric constant of any layer including light source layer 4 except for plasmon excitation layer 15 and a medium that contacts wave number vector conversion layer 17 be as small as possible. When the imaginary part of the complex dielectric constant is set to be as small as possible, the occurrence of plasmon coupling can easily occur in order to reduce optical loss.

Plasmon excitation layer 15 is a fine particle layer or a thin film layer made of a material having a plasma frequency greater than the frequency of light that light source layer 4 emits (light emission frequency). In other words, plasmon excitation layer 15 has a negative dielectric constant at the light emission frequency of light source layer 4.

Examples of the material of plasmon excitation layer 15 include gold, silver, copper, platinum, palladium, rhodium, osmium, ruthenium, iridium, iron, tin, zinc, cobalt, nickel, chromium, titanium, tantalum, tungsten, indium, aluminum, and an alloy thereof. Among them, it is preferable that the material of plasmon excitation layer 15 be gold, silver, copper, platinum, aluminum, or an alloy that contains one of these metals as a primary component. It is more preferable that the material of plasmon excitation layer 15 be gold, silver, platinum, aluminum, or an alloy containing one of these metals as a primary component.

It is preferable that plasmon excitation layer 15 be formed with a thickness of 200 nm or less. It is more preferable that plasmon excitation layer 15 be formed with a thickness around in the range from 10 nm to 100 nm. It is preferable that the distance between the interface of wave number vector conversion layer 17 and plasmon excitation layer 15 and the interface of electron transport layer 13 and hole transport layer 11 be as small as possible. The allowable maximum value of the distance corresponds to the distance in which plasmon coupling occurs between the interface of electron transport layer 13 and hole transport layer 11 and plasmon excitation layer 15. The allowable maximum value of the distance can be calculated using Formula (4).

Wave number vector conversion layer 17 is an emission layer on which a wave number vector of surface plasmons excited on the interface of plasmon excitation layer 15 and wave number vector conversion layer 17 is converted, light is extracted from the interface of plasmon excitation layer 15 and wave number vector conversion layer 17, and then the light is emitted from light emitting element 1. In other words, wave number vector conversion layer 17 converts surface plasmons into light having a predetermined exit angle such that light emitting element 1 emits the resultant light. Namely, wave number vector conversion layer 17 causes light emitting element 1 to emit light in a direction nearly orthogonal to the interface of plasmon excitation layer 15 and wave number vector conversion layer 17.

Examples of wave number vector conversion layer 17 include a surface relief grating; a periodic structure typified by photonic crystal, a quasi-periodic structure, a quasi-crystalline structure; a texture structure having a wavelength greater than that of light emitted from light source layer 4; an uneven surface structure; a hologram; and a micro lens array. The quasi-periodic structure represents an imperfect periodic structure in which a periodic structure is partly lost. Among them, it is preferable that a periodic structure typified by photonic crystal, a quasi-periodic structure, a semi-crystalline structure, or a micro-lens array be used. They can improve light extraction efficiency and control the directivity. When photonic crystal is used, it is preferable that a triangular grating crystalline structure be used. Wave number vector conversion layer 17 may be formed in such a manner that a periodic convex structure or a periodic concave structure is formed on a planar substrate.

Next, the light emitting operation of wave number vector conversion layer 17 of light emitting element 1 having the foregoing structure will be described.

Electrons are injected from part of plasmon excitation layer 15 as a cathode, whereas holes are injected from anode 19. Electrons and holes injected from part of plasmon excitation layer 15 and anode 19 are injected respectively through electron transport layer 13 and hole transport layer 11 into the interface therebetween. The electrons and holes injected into the interface between electron transport layer 13 and hole transport layer 11 are coupled with electrons or holes in plasmon excitation layer 15 and thereby surface plasmons are excited on the interface between plasmon excitation layer 15 and wave number vector conversion layer 17. The surface plasmons excited on the interface are diffracted by wave number vector conversion layer 17. Thereafter, the diffracted surface plasmons are emitted as light having a predetermined exit angle from wave number vector conversion layer 17.

If the dielectric constant on the interface between plasmon excitation layer 15 and wave number vector conversion layer 17 is spatially uniform, namely the interface is a plane, surface plasmons cannot be extracted. Thus, according to the present invention, surface plasmons are diffracted by wave number vector conversion layer 17 so as to extract them as light. Assuming that the exit angle at which light having the highest intensity is extracted is the center exit angle and that the pitch of the periodic structure of wave number vector conversion layer 17 is denoted by ̂, the center exit angle θ_{rad} of light that is emitted from wave number vector conversion layer 17 can be expressed as follows.

$$\begin{matrix}[ Formula 5 ] & \\ {θ}_{rad} = {Sin}^{- 1} ( \frac{{k}_{spp} - i \frac{2 π}{Λ}}{{k}_{0}} ) & Formula ( 5 )\end{matrix}$$

where i is a natural number. Except for the condition in which Formula (5) becomes “0,” light that is emitted from one point of wave number vector conversion layer 17 has a ring-shaped intensity distribution in which the intensity concentrically spreads as light propagates. Under the condition in which Formula (5) becomes “0,” the intensity of light in the direction perpendicular to the plane orthogonal to the direction of the thickness of wave number vector conversion layer 17 of light emitting element 1 is the highest. The intensity is proportional to the angle between the light emission direction of light emitting element 1 and the plane of light emitting element 1. Since the wave number on the interface between plasmon excitation layer 15 and wave number vector conversion layer 17 is a wave number approximately obtained from Formula (3), the angle distribution of emission light obtained from Formula (5) also becomes narrow.

As described above, since the material of light source layer 4 of light emitting element 1 according to the first embodiment is the same as that of an ordinary LED, light emitting element 1 can emit light having as high luminance as high as the LED. In addition, the exit angle of light emitted from wave number vector conversion layer 17 depends on the complex dielectric constant of plasmon excitation layer 15, the effective dielectric constants of the incident side portion and the emission side portion that sandwich plasmon excitation layer 15, and the emission spectrum of light emitted in light emitting element 1. Thus, the directivity of the light emitted from light emitting element 1 is not restricted by the directivity of light source layer 4. In addition, since light emitting element 1 according to this embodiment uses plasmon coupling to emit light, the emission angle of light that is emitted from light emitting element 1 can be narrowed and thereby the directivity of the emission light can be improved.

Thus, according to this embodiment, both luminance and directivity of emission light can be simultaneously improved. In addition, since the directivity of light emitted from light emitting element 1 is improved, the etendue of emission light can be reduced.

Since the manufacturing process of light emitting element 1 according to the first embodiment is similar to that according to the following second embodiment, and the manufacturing process in the first embodiment is the same as the manufacturing process in the second embodiment except that an active layer is formed in the second embodiment, the description of the manufacturing process of light emitting element 1 according to the first embodiment will be omitted.

Next, light emitting elements according to other embodiments of the present invention will be described. Light emitting elements according to other embodiments differ from light emitting element 1 according to the first embodiment only in the structure of light source layer 4 or directivity controlling layer 5. Thus, in the other embodiments of the present invention, only the light source layer or directivity controlling layer that differ from those according to the first embodiment will be described. Similar layers that compose light source layers and directivity controlling layers according to other embodiments to those according to the first embodiment are denoted by similar reference numerals and their description will be omitted.

### Second Embodiment

FIG. 4A is a perspective view schematically showing a light emitting element according to a second embodiment of the present invention. FIG. 4B is a plan view schematically showing the light emitting element according to the second embodiment.

As shown in FIG. 4A and FIG. 4B, light emitting element 2 according to the second embodiment has light source layer 24 and directivity controlling layer 5 that is stacked on light source layer 24 and into which light emitted from light source layer 24 enters. Since directivity controlling layer 5 of light emitting element 2 according to the second embodiment is the same as that according to the first embodiment, the description of directivity controlling layer 5 will be omitted. Light source layer 24 of light emitting element 2 according to the second embodiment is different from light source layer 4 according to the first embodiment only in that active layer 12 is formed between hole transport layer 11 and electron transport layer 13.

The material of active layer 12 of light source layer 24 is the same as that used for an LED or an organic EL. Examples of the material of active layer 12 include InGaN, AlGaAs, AlGaInP, GaN, ZnO, an inorganic material such as diamond (semiconductor), (thiophene/phenylene) co-oligomer, and an organic material such as Alq3 (semiconductor material). It is preferable that active layer 12 have a quantum well structure. In addition, it is preferable that the width of light emission spectrum of active layer 12 be as narrow as possible.

In light emitting element 2 according to the second embodiment, it is preferable that the distance from the interface between wave number vector conversion layer 17 and plasmon excitation layer 15 to the interface between electron transport layer 13 and active layer 12 be as small as possible. The allowable maximum value of the distance corresponds to the distance in which plasmon coupling occurs between active layer 12 and plasmon excitation layer 15. The allowable maximum value of the distance can be calculated using Formula (4).

Moreover, in light emitting element 2 according to the second embodiment, electrons and holes injected from part of plasmon excitation layer 15 and anode 19 are injected into active layer 12 through electron transport layer 13 and hole transport layer 11, respectively. The electrons and holes injected into active layer 12 are coupled with electrons or holes in plasmon excitation layer 15 and thereby surface plasmons are excited on the interface of plasmon excitation layer 15 and wave number vector conversion layer 17. The excited surface plasmons are diffracted by wave number vector conversion layer 17 and emitted from wave number vector conversion layer 17.

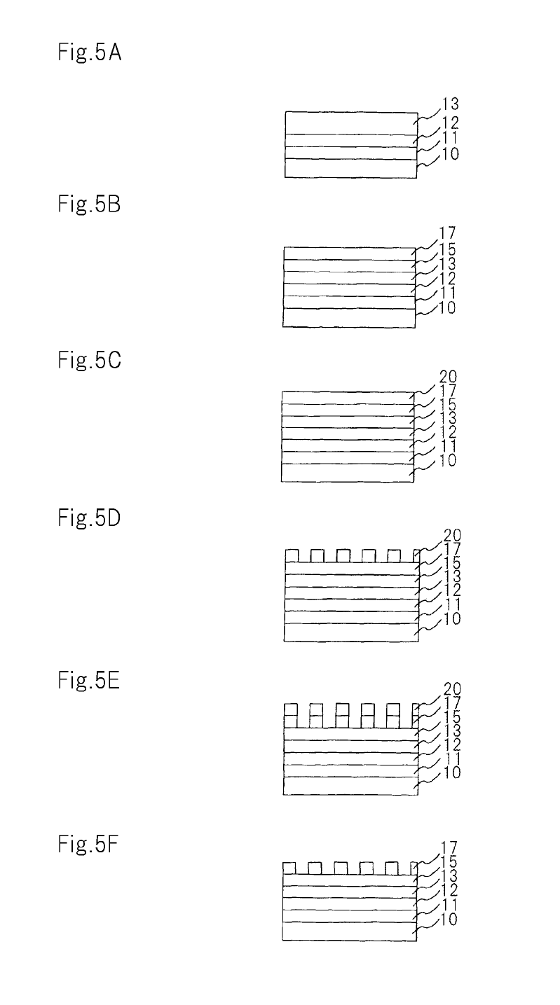

FIG. 5A to FIG. 5F show a manufacturing process of light emitting element 2 according to the second embodiment. The manufacturing process shown in FIG. 5A to FIG. 5F is just an example. Thus, the present invention is not limited to the manufacturing process shown in FIG. 5A to FIG. 5F. As shown in FIG. 5A, since the lamination step that laminates hole transport layer 11, active layer 12, and electron transport layer 13 on substrate 10 is well known, the description of the lamination step will be omitted. As described above, the manufacturing process for light emitting element 1 according to the first embodiment is the same as that according to the second embodiment except that the step that forms active layer 12 is omitted.

Thereafter, as shown in FIG. 5B, plasmon excitation layer 15 and wave number vector conversion layer 17 are successively stacked on electron transport layer 13 according to a technique, for example, physical vapor deposition, electron beam vapor deposition, or sputter vapor deposition.

Thereafter, as shown in FIG. 5C, resist film 20 is coated on wave number vector conversion layer 17 according to the spin coat technique. Thereafter, as shown in FIG. 5D, a negative pattern of photonic crystal is transferred to resist film 20 according to the nanoimprint technique, photolithography technique, or electron beam lithography technique. Thereafter, as shown in FIG. 5E, wave number vector conversion layer 17 is dry-etched for the desired depth. Thereafter, as shown in FIG. 5F, resist film 20 is peeled off from wave number vector conversion layer 17. Finally, the surfaces of plasmon excitation layer 15 and hole transport layer 11 are partly exposed by etching and thereby anode 19 is formed partly on hole transport layer 11. As a result, light emitting element 2 is obtained.

According to this embodiment, substrate 10, hole transport layer 11, active layer 12, electron transport layer 13, and plasmon excitation layer 15 can be formed flat. Since each layer is not structurally restricted, the light emitting element according to this embodiment can be easily manufactured.

### Third Embodiment

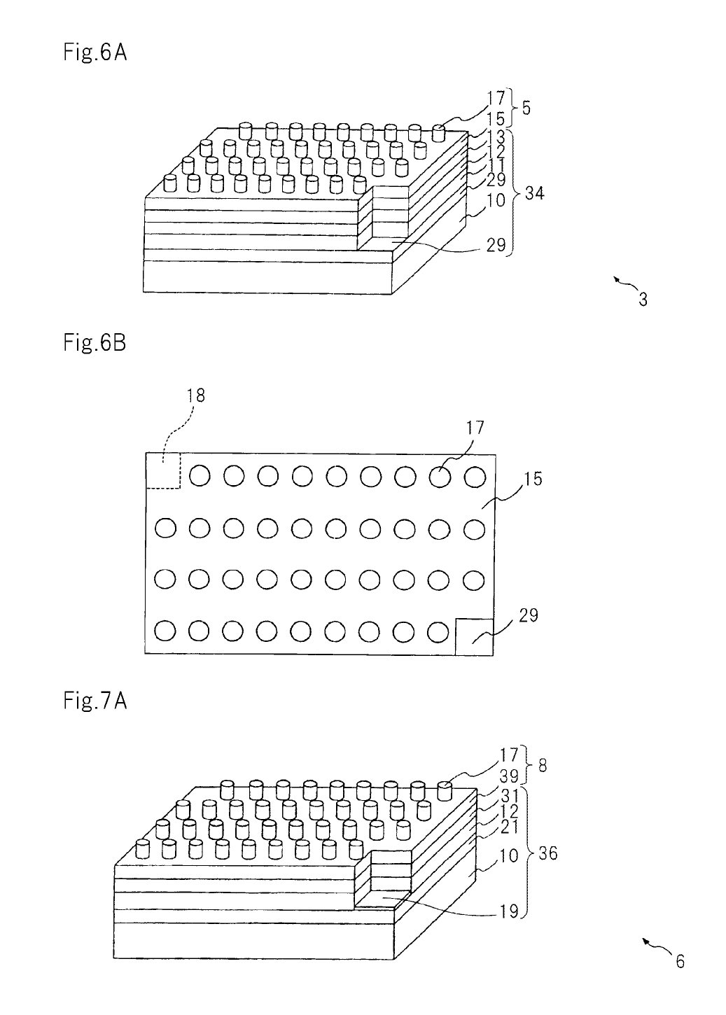

FIG. 6A is a perspective view schematically showing a light emitting element according to a third embodiment of the present invention. FIG. 6B is a plan view schematically showing the light emitting element according to the third embodiment.

As shown in FIG. 6A and FIG. 6B, light emitting element 3 according to the third embodiment has light source layer 34 and directivity controlling layer 5 that is stacked on light source layer 34 and into which light emitted from light source layer 34 enters. Since directivity controlling layer 5 of light emitting element 3 according to the third embodiment is the same as that according to the firth embodiment, the description of directivity controlling layer 5 will be omitted. Light source layer 34 of light emitting element 3 according to the third embodiment is different from light source layer 24 according to the second embodiment in that anode layer 29, that is an anode, is formed completely between substrate 10 and hole transport layer 11.

According to the third embodiment, anode layer 29 operates as a reflection layer that reflects light emitted from active layer 12. Thus, according to the third embodiment, since light emitted from active layer 12 to substrate 10 is reflected to wave number vector conversion layer 17 side, the efficiency at which light is extracted from active layer 12 is improved. Examples of the material of anode layer 29 include Ag, Au, Al, a thin film made of one of these metals as a primary component, and a multi-layer film containing one element from among Ag, Au, and Al. Alternatively, the material of anode layer 29 may be the same as that of an anode of an LED or an organic EL.

According to the third embodiment, anode layer 29 also operates as a heat radiation plate. Thus, anode layer 29 can prevent the internal quantum efficiency from becoming lower as light source layer 34 emits light and generates heat.

Furthermore, anode layer 29 increases the mobility of holes. In most cases, the mobility of holes is lower than that of electrons. Thus, since enough holes are not injected as electrons are injected, the internal quantum efficiency is restricted. In other words, anode layer 29 improves internal quantum efficiency of light source layer 34. Moreover, since anode layer 29 improves the mobility of holes toward the inside of the plane of light emitting element 3, light source layer 34 can uniformly emit light toward the inside of the plane.

A cathode made of a material different from that of plasmon excitation layer 15 may be formed partly or entirely on plasmon excitation layer 15 that is exposed. The materials of the cathode and anode may be the same as those of an LED or an organic EL. When the cathode is formed completely on the exposed surface of plasmon excitation layer 15, it is preferable that the cathode be transparent at the frequency of light emitted from light source layer 4. An anode made of a material different from that of anode layer 29 may be formed at an exposed portion on anode layer 29.

### Forth Embodiment

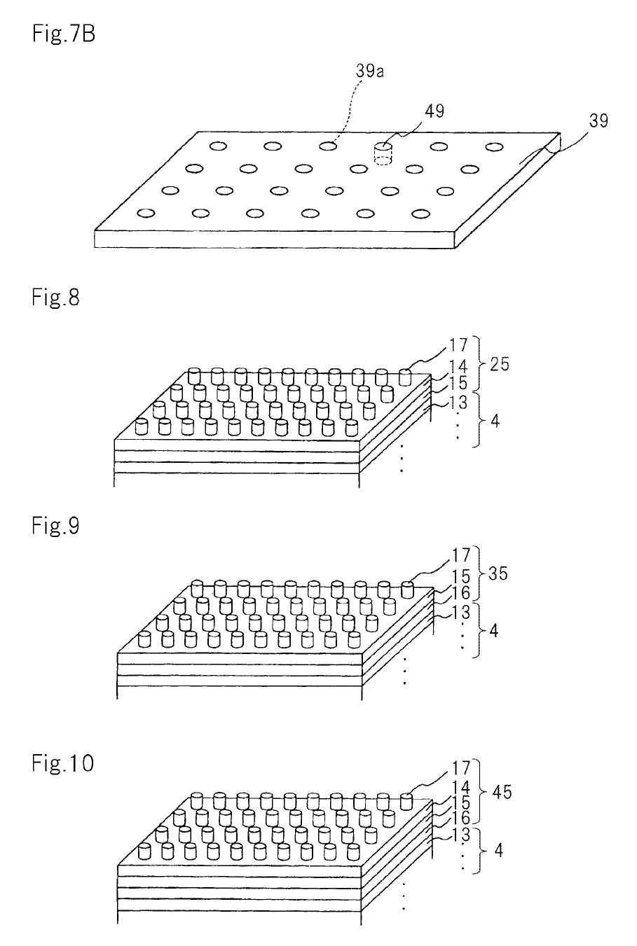

FIG. 7A is a perspective view schematically showing a light emitting element according to a fourth embodiment of the present invention. FIG. 7B is a perspective view schematically showing a plasmon excitation layer of the light emitting element according to the fourth embodiment.

As shown in FIG. 7A and FIG. 7B, light emitting element 6 according to the fourth embodiment has light source layer 36 and directivity controlling layer 8 that is stacked on light source layer 36 and into which light emitted from light source layer 36 enters.

Light source layer 36 according to the fourth embodiment has substrate 10; a pair of electron transport layer 21 and hole transport layer 31 formed on substrate 10; and active layer 12 formed between electron transport layer 21 and hole transport layer 31. According to this embodiment, electron transport layer 21, active layer 12, and hole transport layer 31 are successively stacked on substrate 10. Individual layers formed above electron transport layer 21 are partly cut so as to expose a part of a plane orthogonal to the direction of the thickness of electron transport layer 21. Anode 19 is formed at the exposed portion of electron transport layer 21.

Directivity controlling layer 8 according to the fourth embodiment has plasmon excitation layer 39 that is different from plasmon excitation layer 15 according to the foregoing embodiments in their structures.

As shown in FIG. 7B, plasmon excitation layer 39 has a plurality of through-holes 39a which are pierced in the thickness direction of plasmon excitation layer 39. An electrode material that is a conductive material is buried in through-holes 39a. As a result, a plurality of current injection portions 49 are formed in plasmon excitation layer 39. The electrode material of current injection portions 49 is the same as that used for an LED or an organic EL.

According to this embodiment, the electrode material buried in through-holes 39a of plasmon excitation layer 39 has a work function slightly greater than hole transport layer 31. The relative positions of electron transport layer 21 and hole transport layer 31 may be the reverse of those of this embodiment. In this case, an electrode material having a work function slightly lower than electron transport layer needs to be buried in through-holes 39a.

When hole transport layer 31 formed on directivity controlling layer 8 side is made of GaN, electron transport layer 21 is made of n-type GaN, and plasmon excitation layer 39 is made of Ag, the electrode material of current injection portions 49 is, for example, Ni, Cr, or ITO as an electrode material.

According to this embodiment, even if an adequate ohmic contact cannot be obtained between plasmon excitation layer 39 and electron transport layer 21 or the plasmon excitation layer operates as a barrier, current injection portions 49 of plasmon excitation layer 39 can effectively inject electrons or holes into active layer 12.

Even if the relative positions of electron transport layer 21 and hole transport layer 31 are reverse of those of this embodiment, when current injection portions 49 are formed using an appropriate electrode material, the same effect as the foregoing embodiments can be realized. Alternatively, the current injection portions may have a lamination structure in which a plurality of materials are stacked in the thickness direction of plasmon excitation layer 39.

In the light emitting element of carrier injection type, a material having a slightly greater work function than hole transport layer 31 needs to be used as anode 19 and a material having a slightly lower work function than electron transport layer 21 needs to be used as a cathode so as to effectively inject electrons or holes into active layer 12.

Directivity controlling layer 8 having the foregoing structure according to the fourth embodiment can accomplish the same effect as the first embodiment. In addition, plasmon excitation layer 39 allows electrons or holes to be effectively injected into active layer 12.

### Fifth Embodiment

FIG. 8 is a perspective view showing a directivity controlling layer of a light emitting element according to a fifth embodiment of the present invention. As shown in FIG. 8, directivity controlling layer 25 according to the fifth embodiment has plasmon excitation layer 15 stacked on electron transport layer 13 of light source layer 4; dielectric constant layer 14 stacked on plasmon excitation layer 15; and wave number vector conversion layer 17 stacked on dielectric constant layer 14.

Thus, the fifth embodiment is different from the first embodiment in that dielectric constant layer 14 is independently formed between plasmon excitation layer 15 and wave number vector conversion layer 17. Since dielectric constant layer 14 is set to have a lower dielectric constant than dielectric constant layer 16 (high dielectric constant layer 16) according to a sixth embodiment that will be described later, dielectric constant layer 14 is hereinafter referred to as low dielectric constant layer 14. Low dielectric constant layer 14 needs to have a dielectric constant in the range in which the effective dielectric constant of the emission side portion with respect to plasmon excitation layer 15 is lower than that of the incident side portion. In other words, low dielectric constant layer 14 does not need to have a dielectric constant that is lower than the effective dielectric constant of the incident side portion with respect to plasmon excitation layer 15.

Low dielectric constant layer 14 may be made of a material different from that of wave number vector conversion layer 17. Thus, according to this embodiment, the degree of freedom with respect to the selection of the material of wave number vector conversion layer 17 can be increased.

It is preferable that low dielectric constant layer 14 be a thin film or a porous film made of for example SiO₂, AlF₃, MgF₂, Na₃AlF₆, NaF, LiF, CaF₂, BaF₂, or a plastic having low dielectric constant. It is preferable that the thickness of low dielectric constant layer 14 be as low as possible. The allowable maximum value of the thickness corresponds to the penetration depth of surface plasmons that occur in the direction of the thickness of low dielectric constant layer 14. The allowable maximum value of the thickness can be calculated using Formula (4). Since the plasmon intensity exponentially weakens, if the thickness of low dielectric constant layer 14 exceeds the value calculated using Formula (4), a light emitting element having high efficiency cannot be obtained. In other words, it is necessary that the distance between the plane of wave number vector conversion layer 17, which is the side of plasmon excitation layer 15, and the plane of plasmon excitation layer 15, which is the side of wave number vector conversion layer 17, be equal to or less than the value calculated using Formula (4).

In directivity controlling layer 25 according to the fifth embodiment, the effective dielectric constant of the incident side portion including the entirety of light source layer 4 is set to greater than the effective dielectric constant of the emission side portion including wave number vector conversion layer 17, low dielectric constant layer 14, and a medium that contacts wave number vector conversion layer 17 such that plasmon excitation layer 15 causes plasmon coupling.

Directivity controlling layer 25 having the foregoing structure according to the fifth embodiment can achieve the same effect as the first embodiment. In addition, low dielectric constant layer 14 that is independently formed allows the effective dielectric constant of the emission side portion of plasmon excitation layer 15 to be easily adjusted.

### Sixth Embodiment

FIG. 9 is a perspective view showing a directivity controlling layer of a light emitting element according to a sixth embodiment of the present invention. As shown in FIG. 9, directivity controlling layer 35 according to the sixth embodiment has high dielectric constant layer 16 stacked on electron transport layer 13 of light source layer 24; plasmon excitation layer 15 stacked on high dielectric constant layer 16; and wave number vector conversion layer 17 stacked on plasmon excitation layer 15.

Thus, the sixth embodiment is different from the first embodiment in that dielectric constant layer 16 is independently formed between plasmon excitation layer 15 and electron transport layer 13. Dielectric constant layer 16 is set to have a higher dielectric constant than low dielectric constant layer 14 according to the fifth embodiment. Hereinafter, dielectric constant layer 16 is referred to as high dielectric constant layer 16. High dielectric constant layer 16 needs to have a dielectric constant in the range in which the effective dielectric constant of the emission side portion with respect to plasmon excitation layer 15 is lower than that of the incident side portion. In other words, high dielectric constant layer 16 does not need to have a dielectric constant that is greater than the effective dielectric constant of the emission side portion with respect to plasmon excitation layer 15.

High dielectric constant layer 16 may be made of a material different from that of electron transport layer 13. Thus, according to this embodiment, the degree of freedom with respect to the selection of the material of electron transport layer 13 can be increased.

It is preferable that high dielectric constant layer 16 be a thin film or a porous film made of a high dielectric constant material including one from among diamond, TiO₂, CeO₂, Ta₂O₅, ZrO₂, Sb₂O₃, HfO₂, La₂O₃, NdO₃, Y₂O₃, ZnO, and Nb₂O₅. In addition, it is preferable that high dielectric constant layer 16 be made of a material having conductivity. Moreover, it is preferable that the thickness of high dielectric constant layer 16 be as small as possible. The allowable maximum value of the thickness corresponds to the distance at which plasmon coupling occurs between electron transport layer 13 and plasmon excitation layer 15. The allowable maximum value of the thickness can be calculated using Formula (4).

In directivity controlling layer 35 according to the sixth embodiment, the effective dielectric constant of the incident side portion including light source layer 4 and high dielectric constant layer 16 is set to be higher than the effective dielectric constant of the emission side portion including wave number vector conversion layer 17 and a medium that contacts wave number vector conversion layer 17 such that plasmon excitation layer 15 causes plasmon coupling.

Directivity controlling layer 35 having the foregoing structure according to the sixth embodiment can achieve the same effect as the first embodiment. In addition, high dielectric constant layer 16 that is independently formed allows the effective dielectric constant of the incident side portion of plasmon excitation layer 15 to be easily adjusted.

### Seventh Embodiment

FIG. 10 is a perspective view showing a directivity controlling layer of a light emitting element according to a seventh embodiment of the present invention. As shown in FIG. 10, directivity controlling layer 45 has low dielectric constant layer 14 sandwiched between plasmon excitation layer 15 and wave number vector conversion layer 17; and high dielectric constant layer 16 that is sandwiched between electron transport layer 13 and plasmon excitation layer 15 and that has a higher dielectric constant than low dielectric constant layer 14.

In directivity controlling layer 45 according to the seventh embodiment, the effective dielectric constant of the incident side portion including the entirety of light source layer 4 and high dielectric constant layer 16 is set to be greater than the effective dielectric constant of the emission side portion including wave number vector conversion layer 17, low dielectric constant layer 14, and a medium that contacts wave number vector conversion layer 17 such that plasmon excitation layer 15 causes plasmon coupling.

Directivity controlling layer 45 having the foregoing structure according to the seventh embodiment can achieve the same effect as the first embodiment. In addition, low dielectric constant layer 14 and high dielectric constant layer 16 that are independently formed allow the effective dielectric constant of the emission side portion of plasmon excitation layer 15 and the effective dielectric constant of the incident side portion of plasmon excitation layer 15 to be easily adjusted.

### Eighth Embodiment

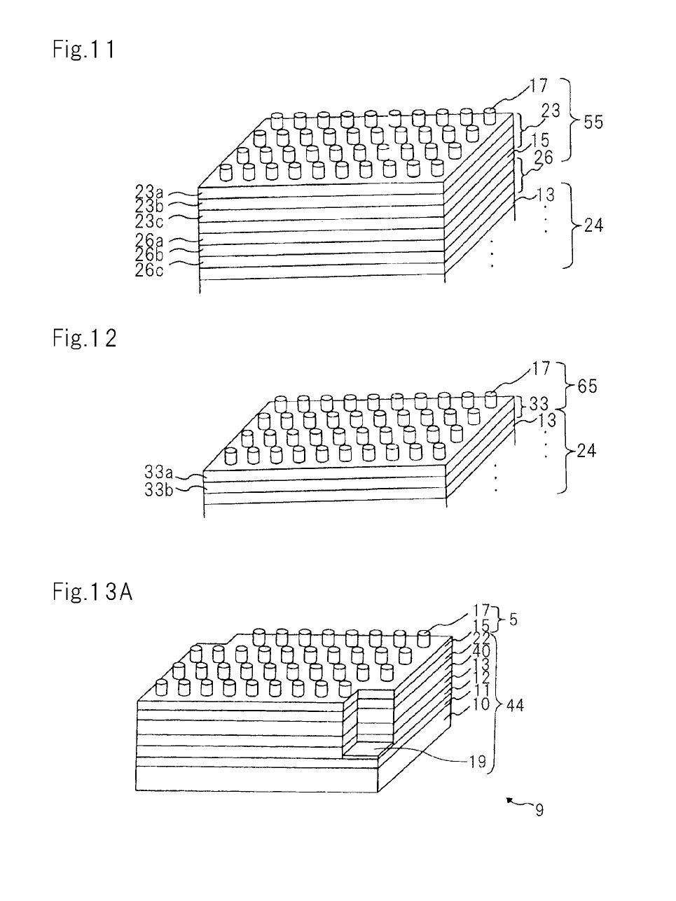

FIG. 11 is a perspective view showing a directivity controlling layer of a light emitting element according to an eighth embodiment of the present invention. As shown in FIG. 11, directivity controlling layer 55 according to the eighth embodiment has the same structure as directivity controlling layer 5 according to the first embodiment except that low dielectric constant layer 14 and high dielectric constant layer 16 according to the seventh embodiment each are each composed of a lamination of a plurality of dielectric constant layers.

In other words, directivity controlling layer 55 according to the eighth embodiment has low dielectric constant layer group 23 composed of a lamination of a plurality of dielectric constant layers 23a to 23c; and high dielectric constant layer group 26 composed of a lamination of a plurality of dielectric constant layers 26a to 26c.

Low dielectric constant layer group 23 is arranged such that the dielectric constants of the plurality of dielectric constant layers 23a to 23c simply decrease in the direction from plasmon excitation layer 15 to wave number vector conversion layer 17 made of a photonic crystal. Likewise, high dielectric constant layer group 26 is arranged such that the dielectric constants of the plurality of dielectric constant layers 26a to 26c simply increase in the direction from electron transport layer 13 of light source layer 24 to plasmon excitation layer 15.

The total thickness of low dielectric constant layer group 23 is set to be equal to the thickness of the low dielectric constant layer according to an embodiment in which the directivity control layer has an independent low dielectric constant layer. Likewise, the total thickness of high dielectric constant layer group 26 is set to be equal to the thickness of the high dielectric constant layer according to an embodiment in which the directivity control layer has an independent high dielectric constant layer. Although low dielectric constant layer group 23 and high dielectric constant layer group 26 are each shown as a structure having three layers, they may have a structure having two to five layers. If necessary, the number of dielectric constant layers of the low dielectric constant layer group may be different from that of the high dielectric constant layer group. Alternatively, the low dielectric constant layer or the high dielectric constant layer may be composed of a plurality of dielectric constant layers.

Since low dielectric constant layer group 23 and high dielectric constant layer group 26 are composed of the plurality of dielectric constant layers 23a to 23c and the plurality of dielectric constant layers 26a to 26c, respectively, the dielectric constants of dielectric constant layers 23c and 26a that are adjacent to the interface of plasmon excitation layer 15 can be adequately set. In addition, the refractive indexes of electron transport layer 13 of light source layer 24, wave number vector conversion layer 17 or a medium such as air that contacts wave number vector conversion layer 17, and low dielectric constant layers 23a and 26c that are adjacent thereto can be set such that they are adequately matched. In other words, high dielectric constant layer group 26 can decrease the difference of refractive indexes on the interface of electron transport layer 13 of light source layer 24 and plasmon excitation layer 15, whereas low dielectric constant layer group 23 can decrease the difference of refractive indexes on the interface of wave number vector conversion layer 17 or the medium such as air and plasmon excitation layer 15.

Directivity controlling layer 55 having the foregoing structure according to the eighth embodiment allows the dielectric constants of dielectric constant layers 23c and 26a that are adjacent to plasmon excitation layer 15 to be adequately set. In addition, directivity controlling layer 55 can decrease the difference of refractive indexes on the interface of electron transport layer 13 of light source layer 24 and plasmon excitation layer 15 and on the interface of wave number vector conversion layer 17 and plasmon excitation layer 15. Thus, directivity controlling layer 55 can further reduce optical loss and improve use efficiency of light emitted from light source layer 24.

Single layer films in which the dielectric constant simply varies may be used instead of low dielectric constant layer group 23 and high dielectric constant layer group 26. In this case, the high dielectric constant layer has a dielectric constant distribution in which the dielectric constant gradually increases in the direction from electron transport layer 13 of light source layer 24 to plasmon excitation layer 15. Likewise, the low dielectric constant layer has a dielectric constant distribution in which the dielectric constant gradually decreases in the direction from plasmon excitation layer 15 to wave number vector conversion layer 17.

### Ninth Embodiment

FIG. 12 is a perspective view showing a directivity controlling layer of a light emitting element according to a ninth embodiment of the present invention. As shown in FIG. 12, the structure of directivity controlling layer 65 according to the ninth embodiment is the same as that of directivity controlling layer 5 according to the first embodiment except that plasmon excitation layer group 33 is composed of a lamination of plurality of metal layers 33a and 33b.

In plasmon excitation layer group 33 of directivity controlling layer 65 according to the ninth embodiment, metal layers 33a and 33b are made of different metal materials and stacked. Thus, plasmon excitation layer group 33 can adjust the plasma frequency.

To raise the plasma frequency of plasmon excitation layer group 33, metal layers 33a and 33b are made of Ag and Al, respectively. To lower the plasma frequency of plasmon excitation layer group 33, metal layers 33a and 33b are made of Ag and Au, respectively. Although plasmon excitation layer group 33 is composed of, for example, two layers, it should be appreciated that, if necessary, plasmon excitation layer group 33 can be composed of three or more metal layers. It is preferable that the thickness of plasmon excitation layer group 33 be 200 nm or less. It is more preferable that the thickness of plasmon excitation layer group 33 be in the range from around 10 nm to 100 nm.

In directivity controlling layer 65 having the forgoing structure according to the ninth embodiment, since plasmon excitation layer group 33 is composed of a plurality of metal layers 33a and 33b, the effective plasma frequency of plasmon excitation layer group 33 can be adjusted to be close to the light emission frequency of active layer 12. Thus, electrons or holes exited in plasmon excitation layer group 33 can be adequately coupled with holes or electrons present in active layer 12. As a result, the efficiency of emission light can be improved.

### Tenth Embodiment

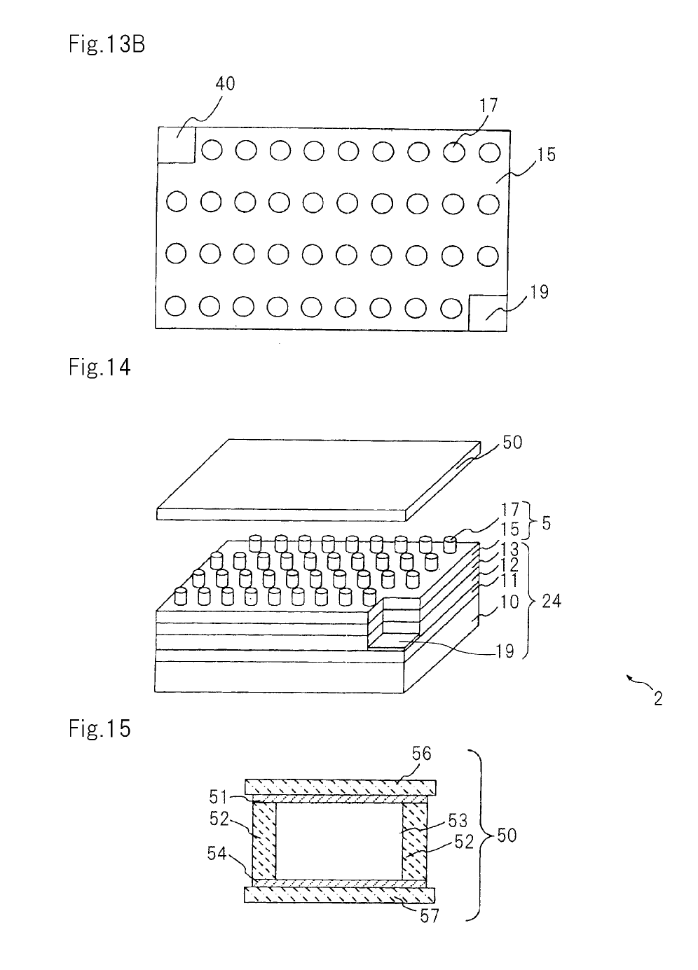

FIG. 13A is a perspective view schematically showing a light emitting element according to a tenth embodiment of the present invention. FIG. 13B is a plan view schematically showing the light emitting element according to the tenth embodiment.

As shown in FIG. 13A and FIG. 13B, light source layer 44 of light emitting element 9 according to the tenth embodiment has a structure of an ordinary LED in which transparent electrode layer 40 is stacked on electron transport layer 13 of light source layer 24 according to the second embodiment. In other words, light source layer 44 has transparent electrode layer 40 stacked on non-substrate 10 side. Moreover, in light source layer 44, active layer 22 that is different from active layer 12 is stacked on transparent electrode layer 40 having the structure of an LED.

Like active layer 22, light source layer 4 according to the first embodiment may have an active layer in which electrons and holes are generated with light emitted from the interface of hole transport layer 11 and electron transport layer 13; and a transparent electrode layer. Light source layer 44 according to the tenth embodiment has anode 19 formed partly on hole transport layer 11. Alternatively, like the third embodiment, anode layer 29 may be formed between substrate 10 and hole transport layer 11.

In light emitting element 9 according to the tenth embodiment, light emitted from activation layer 12 with a current injected into light source layer 44 excites electrons and holes generated in activation layer 22. As described above, when electrons and holes generated in active layer 22 are plasmon-coupled with electrons or holes excited in plasmon excitation layer 15, surface plasmons are excited on the interface between plasmon excitation layer 15 and wave number vector conversion layer 17. The excited surface plasmons are diffracted by wave number vector conversion layer 17 and thereby light having a predetermined wavelength is emitted at a predetermined exit angle.

When light having the desired wavelength is emitted from light emitting element 9 having the foregoing structure according to the tenth embodiment, the degree of freedom with respect to the selection of the light emission material for the active layer can be increased. Although an inorganic material that emits green light having high light emission efficiency with a current that is injected is not known, an inorganic material that emits light having high light emission efficiency with light that is injected is known. According to this embodiment, when a light emission material having such properties is used, if light source layer 44 having active layer 12 and active layer 22 is formed, light obtained with a current injected into active layer 12 can be injected into active layer 22. As a result, the properties of the light emission material used as active layer 22 can be effectively used so as to improve the light emission efficiency of light source layer 44.

(Light Source Device According to Embodiment)

Next, a light source device in which an axially symmetrical polarization half wave plate is arranged on the emission side of light emitting element 2 according to the second embodiment will be described. FIG. 14 is a perspective view describing an axially symmetric polarization half wave plate applied to light emitting element 2.

As shown in FIG. 14, the light source device according to the embodiment has axially symmetric polarization half wave plate 50 as a polarization conversion element that aligns axially symmetrically polarized light that enters from light emitting element 2 into a predetermined polarization state. Axially symmetric polarization half wave plate 50 linearly polarizes incident light of light emitting element 2. Axially symmetric polarization half wave plate 50 is arranged on wave number vector conversion layer 17 side of light emitting element 2. When axially symmetric polarization half wave plate 50 linearly polarizes light emitted from light emitting element 2, the polarization state of the emission light is aligned. Alternatively, the polarization conversion element may align axially symmetrically polarized light in a predetermined polarization state that is in a circularly polarization state instead of in a linearly polarization state. It should be appreciated that the light emitting element according to any one of the foregoing first to tenth embodiments can be applied to the light source device having axially symmetric polarization half wave plate 50.

FIG. 15 is a longitudinal sectional view showing the structure of axially symmetric polarization half wave plate 50. The structure of axially symmetric polarization half wave plate 50 is just an example. Thus, the present invention is not limited to such a structure. As shown in FIG. 15, axially symmetric polarization half wave plate 50 has a pair of glass substrates 56 and 57 on which alignment films 51 and 54 are formed respectively; liquid crystal layer 53 formed between alignment films 51 and 54 of glass substrates 56 and 57; and spacer 52 arranged between glass substrates 56 and 57.

Assuming that the refractive index for ordinary light of liquid crystal layer 53 is denoted by no and the refractive index for extraordinary light of liquid crystal layer 53 is denoted by ne, the refractive index ne will be greater than the refractive index no. The thickness d of liquid crystal layer 53 satisfies the relationship of (ne−no)×d=λ/2. In this case, λ is the wavelength of incident light in vacuum.

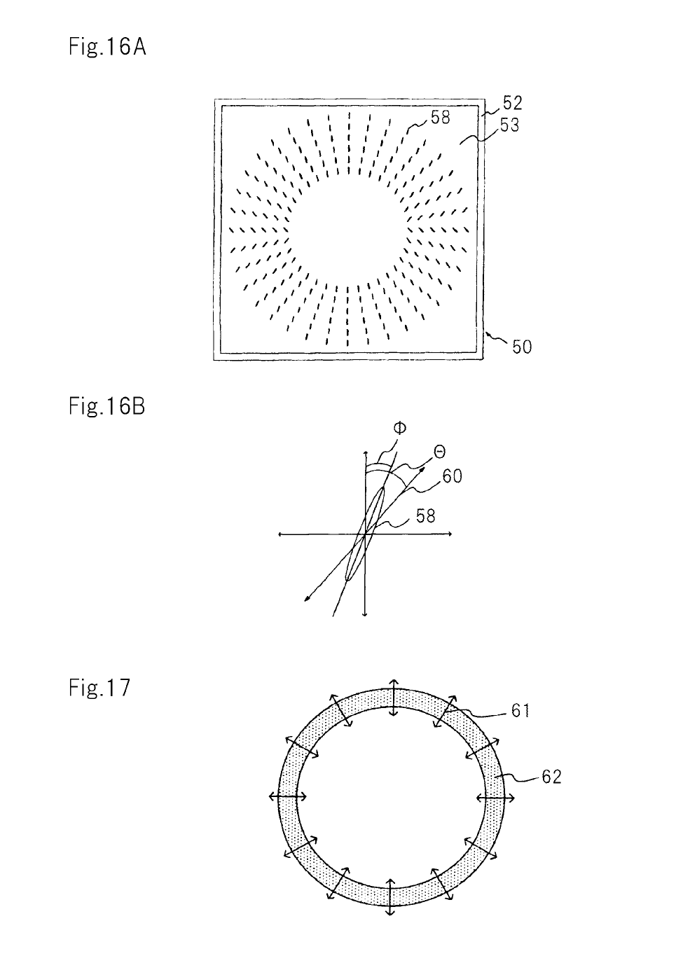

FIG. 16A and FIG. 16B are schematic diagrams describing axially symmetric polarization half wave plate 50. FIG. 16A is a transverse sectional view showing that liquid crystal layer 53 of axially symmetric polarization half wave plate 50 is cut in parallel with the principal planes of glass substrates 56 and 57. FIG. 16B is a schematic diagram describing the alignment direction of liquid crystal molecules 58.

As shown in FIG. 16A, crystal molecules 58 are concentrically arranged around the center of axially symmetric polarization half wave plate 50. As shown in FIG. 16B, assuming that the angle of the principal axis of crystal molecules 58 and the coordinate axis in the neighborhood of the principal axis is denoted by Φ and the angle of the coordinate axis and the polarization direction is denoted by θ, crystal molecules 58 are aligned in the direction that satisfies either θ=2Φ or θ=Φ+90. FIG. 16A and FIG. 16B show the inside of the same plane.

FIG. 17 shows far-field pattern 62 of emission light in the case in which the light emitting element does not have an axially symmetric polarization half wave plate. According to the first to tenth embodiments, far-field pattern 62 of light emitted from light emitting element 2 becomes axially symmetrically polarized light radiated around the optical axis of emission light of light emitting element 2.

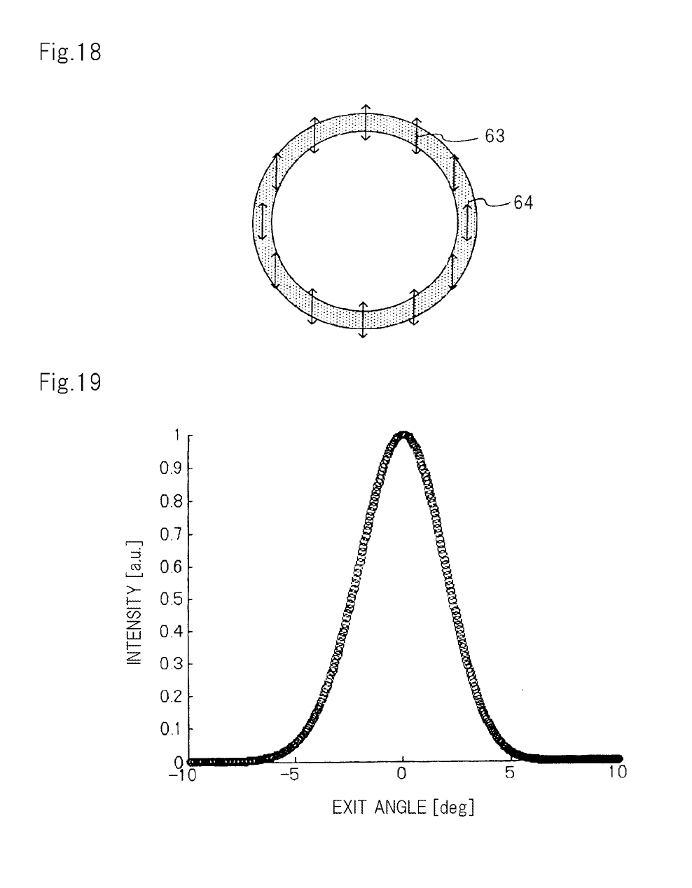

FIG. 18 shows far-field pattern 64 of emission light that passes through axially symmetric polarization half wave plate 50. Axially symmetric polarization half wave plate 50 causes polarization direction 63 of light emitted from light emitting element 2 to be aligned in one direction inside the plane as shown in FIG. 18.

### First Example

FIG. 19 shows an angle distribution of light emitted from light emitting element 2 according to the second embodiment. In FIG. 19, the horizontal axis represents the exit angle of emission light, whereas the vertical axis represents the intensity of emission light.

Substrate 10 made of Al₂O₃, hole transport layer 11 made of GaN:Mg, active layer 12 made of InGaN, electron transport layer 13 made of GaN:Si, and plasmon excitation layer 15 made of Ag were prepared such that their thicknesses became 0.5 mm, 100 nm, 3 nm, 10 nm, and 50 nm, respectively. The medium was air. In addition, the light emission wavelength of light source layer 24 was 460 nm. The material of wave number vector conversion layer 17 was PMMA (polymethyl methacrylate). The depth, pitch, and duty ratio of the periodic structure were set to 100 nm, 321 nm, and 0.5, respectively. Although the emission light under this condition had a luminous intensity distribution similar to a Gaussian function rather than a ring shape, when the pitch was changed from 321 nm, the peak was split and thereby a ring-shaped luminous intensity distribution was obtained.

For simplicity, calculations were made in two dimensions. When the full width of an angle at which the intensity of light emitted from light emitting element 2 is halved is defined as an emission angle, the emission angle of light having a wavelength of 460 nm was ±2.4 (deg).

In this example, from Formula (1), the effective dielectric constants of the emission side portion and incident side portion of plasmon excitation layer 15 were 1.56 and 5.86, respectively. From Formula (2), the imaginary parts of wave numbers in the z direction on the emission side and incident side of the surface plasmons were 9.53×10⁶ and 9.50×10⁷. Assuming that the effective interaction distance of surface plasmons is the distance at which the intensity of surface plasmons becomes e⁻², because of 1/Im (k_{spp,z}), the effective interaction distances of surface plasmons on the emission side and incident side become 105 nm and 10.5 nm, respectively.

Thus, in light emitting element 2 according to the second embodiment, directivity controlling layer 5 can improve the directivity of the emission angle of emission light of light emitting element 2. In addition, when the grating structure of wave number vector conversion layer 17 is adequately adjusted, the emission angle can be narrowed within ±5 degrees so as to further improve the directivity. Moreover, in light emitting element 2 according to the second embodiment, since hole transport layer 11, active layer 12 and electron transport layer 13, that compose light source layer 24, can be made of a p-type semiconductor, an active layer made of an inorganic material and a n-type semiconductor layer made of inorganic semiconductor, respectively, like an ordinary LED, light beams on the order of several thousand lumens can be obtained.

### Second Example

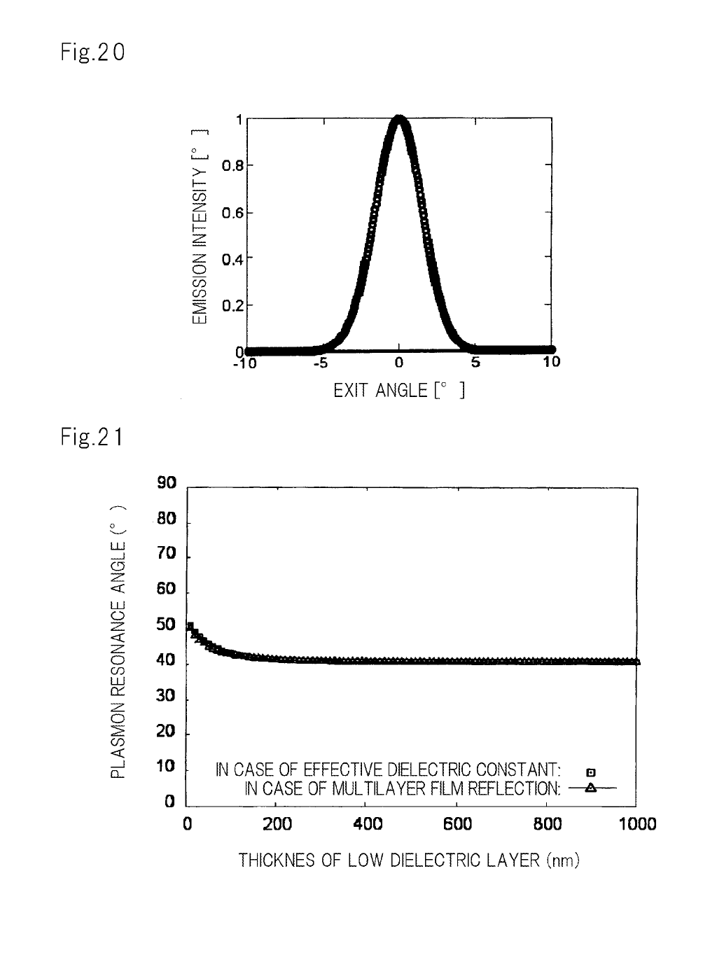

FIG. 20 shows an angle distribution of light emitted from the light emitting element according to the fifth embodiment. In FIG. 20, the horizontal axis represents the exit angle of emission light, whereas the vertical axis represents the intensity of emission light.

Substrate 10 made of Al₂O₃, hole transport layer 11 made of GaN:Mg, active layer 12 made of InGaN, electron transport layer 13 made of GaN:Si, plasmon excitation layer 15 made of Ag, and dielectric constant layer 14 made of SiO₂ were prepared such that their thicknesses became 0.5 mm, 100 nm, 3 nm, 10 nm, 50 nm, and 10 nm, respectively. The medium was air. In addition, the light emission wavelength of light source layer 4 was 460 nm. The material of wave number vector conversion layer 17 was PMMA (polymethyl methacrylate). The depth, pitch, and duty ratio of the periodic structure were set to 100 nm, 321 nm, and 0.5, respectively. Although the emission light under this condition had a luminous intensity distribution similar to a Gaussian function rather than a ring shape, when the pitch was changed from 321 nm, the peak was split and thereby a ring-shaped alignment distribution was obtained.

For simplicity, calculations were made in two dimensions. When the full width of the angle at which the intensity of light emitted from light emitting element 2 is halved is defined as an emission angle, the emission angle of light having a wavelength of 460 nm was ±1.9 (deg).

In this example, from Formula (1), the effective dielectric constants of the emission side portion and incident side portion of plasmon excitation layer 15 were 1.48 and 5.86, respectively. From Formula (2), the imaginary parts of wave numbers in the z direction on the emission side and incident side of the surface plasmons were 8.96×10⁶ and 9.50×10⁷. Assuming that the effective interaction distance of surface plasmons is the distance at which the intensity of surface plasmons becomes e⁻², because of 1/Im (k_{spp,z}), the effective interaction distances of surface plasmons on the emission side and incident side become 112 nm and 10.5 nm, respectively.

FIG. 21 compares a plasmon resonance angle obtained from the effective dielectric constant calculated using Formula (1) (depicted by □ in the drawing) and that obtained by multi-layer film reflection calculations (depicted by Δ in the drawing) with respect to the light emitting element according to the fifth embodiment. The calculation conditions are the same as those in which the angle distribution is obtained except for the thickness of low dielectric constant layer 14. In FIG. 21, the horizontal axis represents the thickness of low dielectric constant layer 14, whereas the vertical axis represents the plasmon resonance angle. As shown in FIG. 21, the calculated value of the effective dielectric constant matches that of multi-layer film reflection. Thus, it is clear that the condition of the plasmon resonance can be defined with the effective dielectric constant using Formula (1).

The light emitting element according to this embodiment can be suitably used for a light source of an image display device. In addition, the light emitting element may be used for a light source with which a projection display device is provided, a direct type light source for a liquid crystal display panel (LCD), a mobile phone as a so-called backlight, an electronic device such as a PDA (Personal Data Assistant), and so forth.

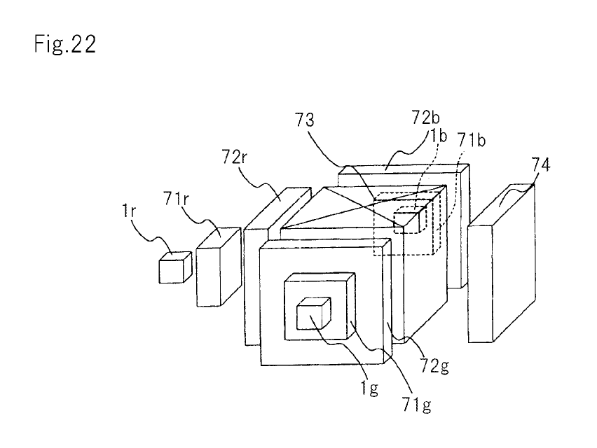

Finally, with reference to FIG. 22, an example of the structure of an LED projector as a projection display device to which a light emitting element according to each of the foregoing first to tenth embodiments is applied will be described. FIG. 22 is a perspective view schematically showing an LED projector according to an embodiment of the present invention.

As shown in FIG. 22, the LED projector according to this embodiment has red (R) light emission element 1r, green (G) light emission element 1g, blue (B) light emission element 1b; illumination optical systems 72r, 72g, and 72b into which emission light of light emission elements 1r, 1g, 1b enters; and light valves 73r, 73g, and 73b as display elements into which light that passes through illumination optical systems 72r, 72g, and 72b enters. In addition, the LED projector has cross dichroic prism 74 that combines R, G, and B light components that are modulated by light valves 73r, 73g, and 73b; and projection optical system 76 including a projection lens (not shown) that projects emission light of cross dichroic prism 74 on a projection plane such as a screen.

The LED projector has a structure applied to a so-called three panel type projector. Illumination optical systems 72r, 72g, and 72b each have a rod lens that equalizes, for example, luminance. Light valves 73r, 73g, and 73b each have, for example, a liquid crystal display panel and a DMD. It should be appreciated that the light emitting element according to the foregoing embodiment can be applied to a single panel type projector.

When the light emitting element according to the foregoing embodiment is applied to the LED projector according to this embodiment, the luminance of projected images can be improved.

In the LED projector, it is preferable that axially symmetric polarization half wave plate 50 shown in FIG. 15 and FIGS. 16A and 16B be arranged on the optical path of light emitted from light emission elements 1r, 1g, and 1r so as to suppress polarization optical loss that occurs in light valves 73r, 73g, and 73b. When the illumination optical systems each have a polarizer, it is preferable that axially symmetric polarization half wave plate 50 be arranged between the polarizers and light emitting element 1.

The present invention has been described with reference to the embodiments. However, it should be understood by those skilled in the art that the structure and details of the present invention may be changed in various manners without departing from the scope of the present invention.

The present application claims priority based on Japanese Patent Application JP 2010-053094 filed on Mar. 10, 2010, the entire contents of which are incorporated herein by reference in its entirety.

What is claimed is:

1.-22. (canceled)

23. A light emitting element, comprising:
a light source layer; and
an optical element layer that is laminated on the light source layer and into which light emitted from the light source layer enters,
wherein said light source layer has a substrate and a pair of a hole transport layer and an electron transport layer formed on the substrate,
wherein said optical element layer has:
a plasmon excitation layer that is laminated on a non-substrate side of said light source layer and that has a higher plasma frequency than light emitted from said light source layer, and
an emission layer that is laminated on said plasmon excitation layer and that converts surface plasmons that are generated in said plasmon excitation layer into light having a predetermined exit angle and emits the light having the predetermined exit angle,
wherein said plasmon excitation layer is sandwiched between two layers having dielectricity, and
wherein an effective dielectric constant of an incident side portion including an entire structure laminated on said light source layer side of said plasmon excitation layer is greater than that of an emission side portion including an entire structure laminated on said emission layer side of said plasmon excitation layer and a medium that contacts said emission layer.

24. The light emitting element according to claim 23,
wherein said effective dielectric constant is determined based on a dielectric constant distribution of dielectrics in the incident side portion or the exit side portion and based on a distribution of a surface plasmon in the direction vertical to the interface of the plasmon excitation layer in the incident side portion or the exit side portion.

25. The light emitting element according to claim 23, further comprising:
a dielectric constant layer formed adjacently to at least one layer of said emission layer side of said plasmon excitation layer and said light source layer side of said plasmon excitation layer.

26. The light emitting element according to claim 25,
wherein said plasmon excitation layer is sandwiched between a pair of said dielectric constant layers, and
wherein said dielectric constant layer adjacent to said light source layer side of said plasmon excitation layer has a higher dielectric constant than said dielectric constant layer adjacent to said emission layer side of said plasmon excitation layer.

27. The light emitting element according to claim 25,
wherein said dielectric constant layer formed adjacent to said emission layer side of said plasmon excitation layer is composed of a lamination of a plurality of dielectric constant layers having different dielectric constants, and
wherein said plurality of dielectric constant layers are arranged in such a manner that their dielectric constants decrease in the direction from said plasmon excitation layer side to said emission layer side.

28. The light emitting element according to claim 25,
wherein said dielectric constant layer formed adjacent to said emission layer side of said plasmon excitation layer is composed of a lamination of a plurality of dielectric constant layers having different dielectric constants, and
wherein said plurality of dielectric constant layers are arranged in such a manner that their dielectric constants increase in the direction from said light source layer to said plasmon excitation layer side.

29. The light emitting element according to claim 25,
wherein said dielectric constant layers formed adjacent to said emission layer side of said plasmon excitation layer have a dielectric constant distribution in which the dielectric constants gradually decrease in a direction from said plasmon excitation layer side to said emission layer side.

30. The light emitting element according to claim 25,
wherein said dielectric constant layers formed adjacent to said light source layer side of said plasmon excitation layer have a dielectric constant distribution in which their dielectric constants gradually increase in a direction from said light source layer side to said plasmon excitation layer side.

31. The light emitting element according to claim 25,
wherein said dielectric constant layer formed adjacent to said emission layer side of said plasmon excitation layer is a porous layer.

32. The light emitting element according claim 25,
wherein said dielectric constant layer formed adjacent to said light source layer side of said plasmon excitation layer has conductivity.

33. The light emitting element according to claim 23, further comprising:
an active layer formed between said hole transport layer and said electron transport layer and that emits light.

34. The light emitting element according to claim 23,
wherein said plasmon excitation layer is composed of a lamination of a plurality of metal layers made of different metal materials.

35. The light emitting element according to claim 23,
wherein said emission layer has a surface periodic structure.

36. The light emitting element according to claim 23,
wherein one of said pair of hole transport layer and electron transport layer that is formed on said substrate side has an exposed portion on a plane orthogonal to a direction of the thickness, an electrode being formed at the exposed portion.

37. The light emitting element according to claim 23, further comprising:
an electrode layer formed between said substrate and any one of said pair of hole transport layer and electron transport layer.

38. The light emitting element according to claim 23,
wherein part of a plane orthogonal to the thickness direction of said plasmon excitation layer is exposed and a current is supplied to the part.

39. The light emitting element according to claim 23,
wherein said light source layer has a transparent electrode layer laminated on a non-substrate side; and an active layer that is laminated on the transparent electrode layer and that generates electrons and holes with light emitted between said hole transport layer and said electron transport layer, and
wherein said plasmon excitation layer has a higher plasma frequency than light generated in said active layer exited with light emitted between said hole transport layer and said electron transport layer.

40. The light emitting element according to claim 23,
wherein said plasmon excitation layer has a plurality of through-holes which are pierced in the thickness direction and a conductive material buried in said plurality of through-holes.

41. The light emitting element according to claim 23,
wherein said plasmon excitation layer is made of any one metal from among Ag, Au, Cu, Pt, Al, and an alloy containing at least one of these metals.

42. A light source device, comprising:
a light emitting element according to claim 23; and
a polarization conversion element that aligns axially symmetric polarized light that enters from said light emitting element in a predetermined polarization state.

43. A projection display device, comprising:
a light emitting element according to claim 23;
a display element that modulates light emitted from said light emitting element; and
a projection optical system that projects an image with the emission light of said display device.

44. A projection display device, comprising:
a light emitting element according to claim 23;
a display element that modulates emission light of said light emitting element;
a projection optical system that projects an image with light emitted from said light emitting element; and
a polarization conversion element that is arranged on an optical path between said light emitting element and said display element and that aligns axially symmetric polarized light that enters from said light emitting element into a predetermined polarization state.
